(19) United States
(12) Patent Application Publication
(10) Pub. No.: US 2009/0002074 A1
(43) Pub. Date: Jan. 1, 2009

(54) Power Supply Control Circuit

(76) Inventors: Hideaki Kushida, Saitama (JP); Hiroshi Saito, Saitama (JP); Hiroyasu Nakano, Saitama (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/658,698

(22) PCT Filed: Jul. 27, 2005
(86) PCT No.: PCT/JP2005/014134

§ 371 Date: Jan. 29, 2007

(30) Foreign Application Priority Data
Jul. 29, 2004 (JP) 2004-222370

(51) Int. Cl. H03F 1/00; H03F 3/217

(52) U.S. Cl. 330/297; 330/251

(57) ABSTRACT

The present invention is to provide a power supply control circuit that can effectively eliminate voltage distortion of an input signal during signal amplification. A power supply control circuit which controls a power supply voltage of a direct-current power source at a constant level and supplies the power supply voltage to an amplification circuit performing a differential operation alternately in accordance with a signal level of an input signal includes: a first transistor whose collector is connected to the direct-current power source and emitter is connected to the amplification circuit, for outputting a current; an error amplifier whose output port is connected to a base of the first transistor, for performing feedback control to hold a difference between a predetermined reference potential and a potential at the emitter of the first transistor at a constant level; and a second transistor whose emitter and base are mutually connected to the first transistor and collector is grounded, for absorbing a current.

### TECHNICAL FIELD

The present invention relates to a power supply control circuit, and is preferably applied to a portable MD. (Mini Disc) player, for example.

### BACKGROUND ART

This kind of portable MD player has been equipped with a secondary battery as a current supply source such as a lithium-ion battery. The MD player reproduces an audio signal from a MD and then amplifies the audio signal to output it through a speaker.

The MD player pulse width modulates the audio signal which was reproduced from the MD to generate a PWM (Pulse Width Modulation) signal. The MD player then amplifies the PWM signal through a power amplification circuit in accordance with power supply voltage supplied from the secondary battery to supply power to the speaker.

In recent years, the power amplification circuit including an energy-efficient class-D amplifier (i.e. a digital amplifier) and a low-pass filter is often utilized (see Patent Document 1, for example). FIG. 6 illustrates the internal configuration of components of the MD player: a power amplification circuit 1 and a power supply control circuit 2.

As shown in FIG. 6, the power amplification circuit 1 includes serially connected circuits: a single-ended class-D amplifier 3, a low-pass filter 4, and a coupling capacitor 5. In the class-D amplifier 3, gates of a PMOS transistor 9 and NMOS transistor 10 are connected to output ports of an amplification circuit 7 and inverting amplification circuit 8, respectively. The amplification circuit 7 and the inverting amplification circuit 8 are connected to one another through a connection midpoint which is equivalent to an input port 6 of a PWM signal S1. Both MOS transistors 9 and 10 operate alternately.

Drains of the PMOS transistor 9 and NMOS transistor 10 are connected to one another and then connected to the low-pass filter 4. A source of the PMOS transistor 9 is connected to an output port of the power supply control circuit 2, while a source of the NMOS transistor 10 is grounded.

The low-pass filter 4 includes a coil 11 whose one end is connected to a connection midpoint P1 which is equivalent to a common drain where the drains of the PMOS transistor 9 and NMOS transistor 10 are connected to one another and other end is connected to the coupling capacitor 5; and a capacitor 12 whose one end is connected to the other end of the coil 11 and other end is grounded.

The power supply control circuit 2 includes a NPN transistor 13 for outputting a current; and an error amplifier 14 for correcting a voltage. The collector of the NPN transistor 13 is connected to a secondary battery 15, its emitter is connected to the power amplification circuit 1, and its base is connected to an output port of the error amplifier 14.

The error amplifier 14 includes an operational amplifier with two input ports and one output port. One of the input ports is connected to a predetermined voltage generator (not shown) to be kept at a reference potential E1. The other end of the input ports is connected to the emitter of the NPN transistor 13.

The power supply control circuit 2 supplies a current from the secondary battery 15 to the class-D amplifier 3 of the power amplification circuit 1 through the NPN transistor 13. In addition, to hold a differential voltage measured between the emitter of the NPN transistor 13 of the error amplifier 14 and the reference potential E1 at a constant level, the power supply control circuit 2 applies the differential voltage to the base of the NPN transistor 13 as a correction voltage.

In the power amplification circuit 1, at a time when the PWM signal S1 (FIG. 7(C)) which corresponds to an audio signal reproduced from a MD is supplied alternately to the bases of the PMOS transistor 9 and NMOS transistor 10 through the amplification circuit 7 and the inverting amplification circuit 8, the connection midpoint P1 puts together drain currents of the PMOS transistor 9 and NMOS transistor 10 of the class-D amplifier 3 which are supplied from the secondary battery 15 via the power supply control circuit 2 and outputs it to a subsequent stage of the low-pass filter 4.

The low-pass filter 4 integrates the PWM signal S1, which has been amplified by the class-D amplifier 3, by the combination of the coil 11 and the capacitor 12 to reproduce an original sine-wave audio signal S2. The low-pass filter 4 then outputs the audio signal S2 to a speaker 16 after removing direct-current components through the coupling capacitor 5.

### Patent Document 1 Japanese Patent Publication No. 2002-262576.

However, in the power supply control circuit 2 with the above configuration (FIG. 6), the coil 11 which is a part of the low-pass filter 4 accumulates energy during a negative half-cycle of the sine-wave audio signal S2 output from the power amplification circuit 1, and this generates a back electromotive force.

The current which is generated by the back electromotive force at the coil 11 is fed into a feedback loop (a connection midpoint P2) of an error amplifier 14 of the power supply control circuit 2 through the connection midpoint P1, which is the common drain of the PMOS transistor 9 and NMOS transistor 10 of the class-D amplifier 3, and the source of the PMOS transistor 9.

Accordingly, in the power supply control circuit 2, the voltage at the emitter of the NPN transistor 13 changes only during the negative half-cycle of the sine-wave audio signal S2. Therefore, even if the error amplifier 14 corrects the power supply voltage of the secondary battery 15 (FIG. 7(A)) to hold it at a constant level, the voltage at the emitter of the NPN transistor 13 continues to change (FIG. 7(B)).

As a result, in the class-D amplifier 3 of the power amplification circuit 1, the voltage of the audio signal S2, which is generated based on the power supply voltage of the secondary battery 15, is distorted during the negative half-cycle (FIG. 7(D)). This adversely affects quality of the sound which is output, based on the audio signal S2, through the speaker 16.

### DISCLOSURE OF THE INVENTION

The present invention has been made in view of the above points and is intended to provide a power supply control circuit that can effectively eliminate voltage distortion of an input signal during signal amplification.

To solve the above problems, in the present invention, a power supply control circuit which controls a power supply voltage of a direct-current power source at a constant level and supplies the power supply voltage to an amplification circuit performing a differential operation alternately in accordance with a signal level of an input signal includes: a first transistor whose collector is connected to the direct-current power source and emitter is connected to the amplification circuit, for outputting a current; an error amplifier whose output port is connected to a base of the first transistor, for performing feedback control to hold a difference between a predetermined reference potential and a potential at the emitter of the first transistor at a constant level; and a second transistor whose emitter and base are mutually connected to the first transistor and collector is grounded, for absorbing a current, wherein an emitter current of the first transistor is supplied to the amplification circuit, while a current that is supplied at certain timing determined by the input signal from the amplification circuit is fed into the ground through the second transistor.

Accordingly, in the power supply control circuit, even if the current is fed from the amplification circuit at certain timing determined by the input signal, the current is fed into the ground through the second transistor, which is the one for absorbing a current, without going through a feedback loop of the error amplifier. This prevents the potential at the emitter of the first transistor, which is the one for outputting a current, from changing. Thus, that prevents voltage distortion of the input signal in the amplification circuit.

### BRIEF DESCRIPTION OF THE DRAWINGS

FIG. 1 is a block diagram illustrating the configuration of a recording and reproduction device according to a first embodiment of the present invention.

FIG. 2 is a block diagram illustrating the internal configuration of a power supply control circuit for class-D and a class-D power amplification circuit shown in FIG. 1.

FIG. 3 is a diagram showing signal waveforms for explaining correction of voltage distortion of an audio signal.

FIG. 4 is a graph illustrating characteristics of frequencies and distortion rates of an audio signal.

FIG. 5 is a block diagram showing the internal configuration of a power supply control circuit for class-D and a class-D power amplification circuit according to a second embodiment of the present invention.

FIG. 6 is a block diagram showing the internal configuration of a conventional power supply control circuit and a power amplification circuit.

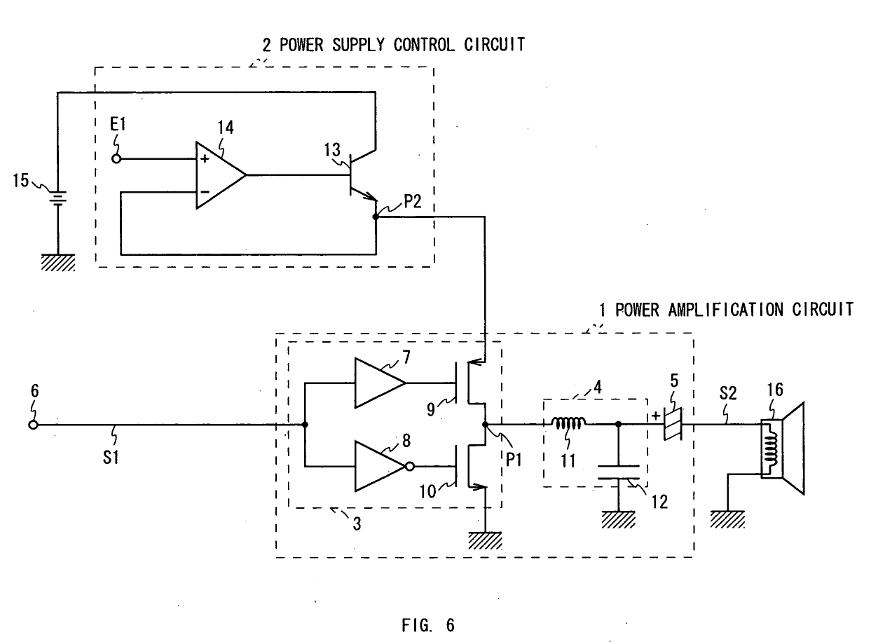

FIG. 7 is a diagram showing conventional signal waveforms for explaining voltage distortion of an audio signal.

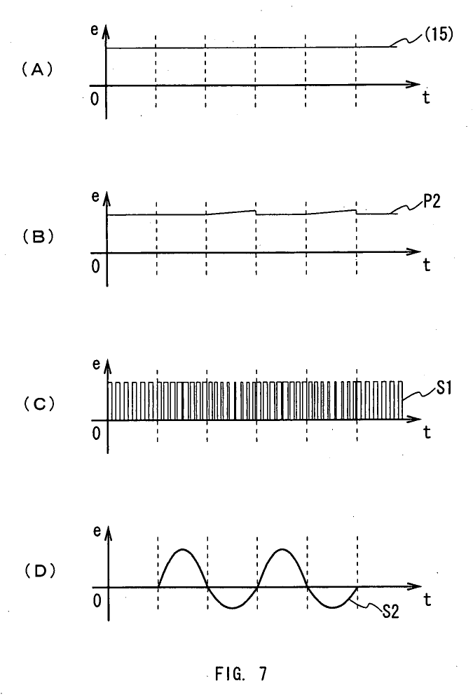

### BEST MODE FOR CARRYING OUT THE INVENTION

An embodiment of the present invention will be described in detail with reference to the accompanying drawings.

### (1) First Embodiment

### (1-1) Configuration of Recording and Reproduction Device according to First Embodiment

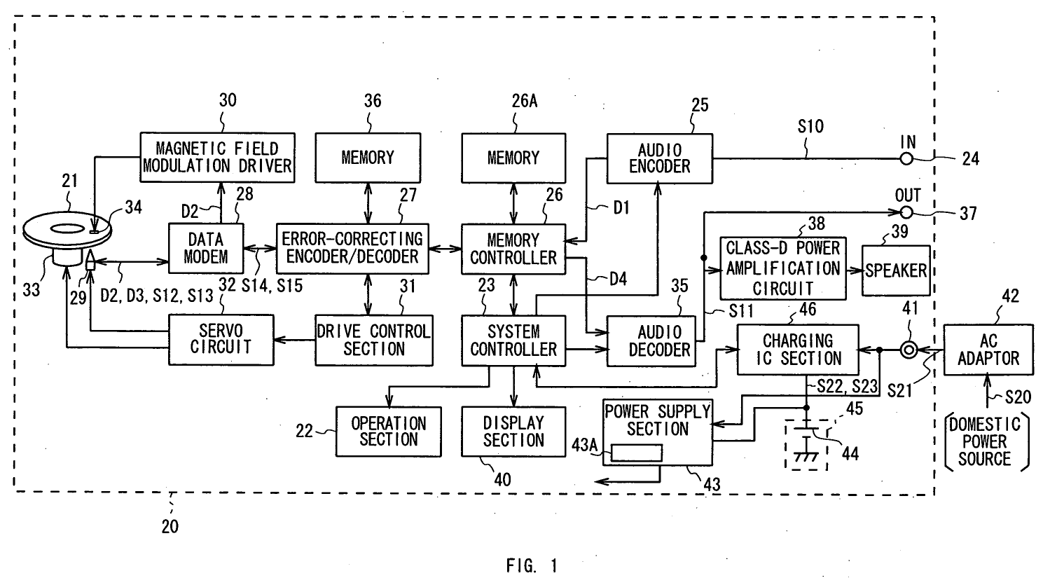

In FIG. 1, the reference numeral 20 denotes a recording and reproduction device according to a first embodiment of the present invention as a whole. The recording and reproduction device 20 records an audio signal S10, which is supplied from outside, on a magneto optical disc 21 such as MD (Mini Disc). The recording and reproduction device 20 reproduces an audio signal S11 from the magneto optical disc 21 and then outputs the audio signal S11 to outside.

In a case in which a user chooses a recording mode by operating an operation section 22, a system controller 23 that takes overall control of the recording and reproduction device 20 feeds the audio signal S10, which is sequentially supplied from outside, into the audio encoder 25 through an input port 24 to perform a predetermined encoding process which then produces encoded audio data D1. The recording and reproduction device 20 subsequently supplies the encoded audio data D1 to a memory controller 26.

The memory controller 26 is utilizing a memory 26A as a buffer when needed to supply the encoded audio data D1 to an error-correcting encoder/decoder 27 which then adds a predetermined error-correcting code to each sector of 2 [kbyte]. The encoded audio data D1 is subsequently fed into a data modem 28 which then performs an EFM (Eight to Fourteen Modulation) process to produce a recording data D2. The data modem 28 then supplies the recording data D2 to an optical pickup 29 and a magnetic field modulation driver 30.

The optical pickup 29 includes optical devices such as a laser diode, a collimator lens, an objective lens and a light-sensitive element; and electric devices such as a laser diode driver. The optical pickup 29 emits an optical beam, which has been modulated based on the recording data D2 supplied, to a recording surface of the magneto optical disc 21.

At that time, the optical pickup 29 generates, based on reflection from the magneto optical disc 21, a servo error signal S12 including a tracking error signal and a focus error signal, and a push-pull signal S13. The optical pickup 29 then feeds these signals S12 and S13 into a drive control section 31 through the data modem 28 and the error-correction encoder/decoder 27.

Based on the servo error signal S12 supplied, the drive control section 31 drives, by controlling a servo circuit 32, a spindle motor 33. This rotates the magneto optical disc 21 at a predetermined speed. In addition, based on the servo error signal S12, the drive control section 31 drives, by controlling the magnetic field modulation driver 30 through the error-correcting encoder/decoder 27 and the data modem 28, a sled motor 34 to move a beam spot of the optical beam on the magneto optical disc 21 (simply referred to as a beam spot below) along a data track (pre-grooves and lands) formed on the recording surface of the magneto optical disc 21 in a radial direction of the magneto optical disc 21.

Furthermore, based on the servo error signal S12, the drive control section 31 drives, by controlling the servo circuit 32, a two-axis actuator (not shown) inside the optical pickup 29 to perform tracking and focusing controls.

On the other hand, the data modem 28 decodes the supplied push-pull signal S13 to obtain an absolute address of the beam spot formed on the magnet optical disc 21 at that time. The data modem 28 then supplies the absolute address to the system controller 23 through the error-correcting encoder/decoder 27 and the memory controller 26.

That is to say, the data modem 28 inputs the push-pull signal S13 into a internal band-pass filter with a center frequency of 22.05 [Hz] and bandwidth of ±1 [kHz] to remove wobble components from the push-pull signal S15. At this time, the data modem 28 performs FM demodulation on the wobble components to obtain the absolute address of the magnet optical disc 21 where the beam spot exists. The data modem 28 subsequently supplies the absolute address to the system controller 23 as address information S14 through the error-correcting encoder/decoder 27 and the memory controller 26.

Each time when the absolute address on the magneto optical disc 21 (which is obtained by the above decoding process) changes (i.e. the beam spot starts to scan a different sector on the magneto optical disc 21), the data modem 28 supplies a sync interrupt signal S15 to the system controller 23 through the error-correcting encoder/decoder 27 and the memory controller 26 to notify the system controller 23 of that fact.

The system controller 23 in turn recognizes, based on the address information signal S14 and sync interrupt signal S15 supplied from the data modem 28, a recording position on the magneto optical disc 21 at that time. Based on the result of recognizing the recording position, the system controller 23 performs an appropriate control process so that the recording data D2 is properly recorded on the magneto optical disc 21.

When the user chooses a reproducing mode by operating the operation section 22, the system controller 23 rotates, by controlling the drive control section 31 in the same way as the above recording mode, the magneto optical disc 21 at a predetermined speed. In addition, the system controller 23 moves the beam spot along the data track on the magneto optical disc 21, and the system controller 23 also performs tracking and focusing controls.

The system controller 23 activates the laser diode inside the above optical pickup 29 to emit an optical beam to the magneto optical disc 21. The recording surface of the magneto optical disc 21 reflects the optical beam. The read data D3 read out from the magneto optical disc 21, which is equivalent to a RF signal generated from the reflection, is fed into the error-correcting encoder/decoder 27 from the optical pickup 29 through the data modem 28.

The error-correcting encoder/decoder 27 includes the following circuits (not shown): a PLL (Phase Locked LOOP) circuit, a synchronous data detection section, an EFM demodulation section, a CIRC decoding section and a layered ECC demodulation section. The PLL circuit extracts a clock from the read data D3 supplied, and then supplies the extracted clock, along with the read data D3, to the synchronous data detection section.

The synchronous data detection section generates, based on the clock supplied, a window pulse for detection of synchronous data, whose width is larger than that of the data pattern of the above synchronous data by including predetermined bits in its front and back ends. And then, the synchronous data detection section sequentially detects the window pulse for detection of synchronous data. Based on the result of detecting the window pulse, the synchronous data detection section sequentially supplies a predetermined unit of the read data D3 to the EFM demodulation section.

The read data D3 is then converted into an original format of audio data D4 by an EFM demodulation process of the EFM demodulation section, a CIRC demodulation process of the CIRC decoding section and an error-correcting process of the layered ECC demodulation section. The audio data D4 is supplied to an audio decoder 35 through the memory controller 26. By the way, while the above processes are being performed, the error-correction decoder/encoder 27 utilizes a memory 36 as a buffer when needed.

The audio decoder 35 performs a predetermined demodulation process on the audio data D4 to generate an audio signal S11, and then outputs the audio signal S11 through an output port 37 to outside. At the same time, the audio decoder 35 amplifies the audio signal S11 by a class-D power amplification circuit 38, and then outputs audio through a speaker 39.

In this manner, the recording and reproduction device 20 records the audio signal S10, which is supplied from outside, on the magneto optical disc 21. In addition, the recording and reproduction device 20 reproduces the audio signal S11 from the magneto optical disc 21 and then outputs the audio signal S11 to outside or the speaker 39.

By the way, the system controller 23 of the recording and reproduction device 20 displays various associated information added to the audio data D4 (such as title names, recording or playback time) on a display screen of a display section 40 such as a LCD (Liquid Crystal Display) in both the recording mode and the reproducing mode.

The recording and reproduction device 20 includes a DC (Direct Current) input port 41 which is connected to an one end of an AC adaptor 42 whose other end is connected to a domestic power source (not shown). In this manner, the recording and reproduction device 20 utilizes the domestic power source as its source of power.

When the AC adaptor 42 is connected to the domestic power source and the DC input port 41, an alternating current S20 from the domestic power source is converted into a direct current S21 with a value of rated current of the AC adaptor 42. The direct current S21 is then supplied to a power supply section 43 through the DC input port 41.

The power supply section 43 supplies the supplied direct current S21 to each circuit of the recording and reproduction device 20 as a system current. At this time, the power supply section 43 detects a current value of the system current S22 which is supplied to all the circuits, and then notifies the system controller 23 of the detected value at predetermined timing.

The recording and reproduction device 20 with the above configuration further includes a battery storage space 45 where a secondary battery 44 (such as lithium-ion battery) is fixed or mounted in removable manner. In a case in which a user brings out the recording and reproduction device 20, the recording and reproduction device 20 utilizes the secondary battery 44 in the battery storage space 45 as its power source. That is to say, the secondary battery 44 in the battery storage space 45 supplies the charged current to all the circuits as the system current S22 through the power supply section 43 when it is used.

The secondary battery 44 in the battery storage space 45 can be charged by the direct current S21 which is supplied from the outside domestic power source through the DC input port 41 and the AC adaptor 42. In this case, the recording and reproduction device 20 includes a charging IC (Integrated Circuit) section 46 between the DC input port 41 and the battery storage space 45. The charging IC section 46 under the control of the system controller 23 controls the current value of the direct current S21 which is supplied through the DC input port 41, and then supplies the direct current to the secondary battery 44 in the battery storage section 45 as a charging current S23.

### (1-2) Configuration of a Power Supply Control Circuit for Class-D and a Class-D Power Amplification Circuit according to First Embodiment

In addition to that, the power supply section 43 includes a power supply control circuit for class-D 43A. Through the power supply control circuit for class-D 43A, the power supply section 43 supplies the power supply voltage from the secondary battery 44 to the class-D power amplification circuit 38 followed by the speaker 39.

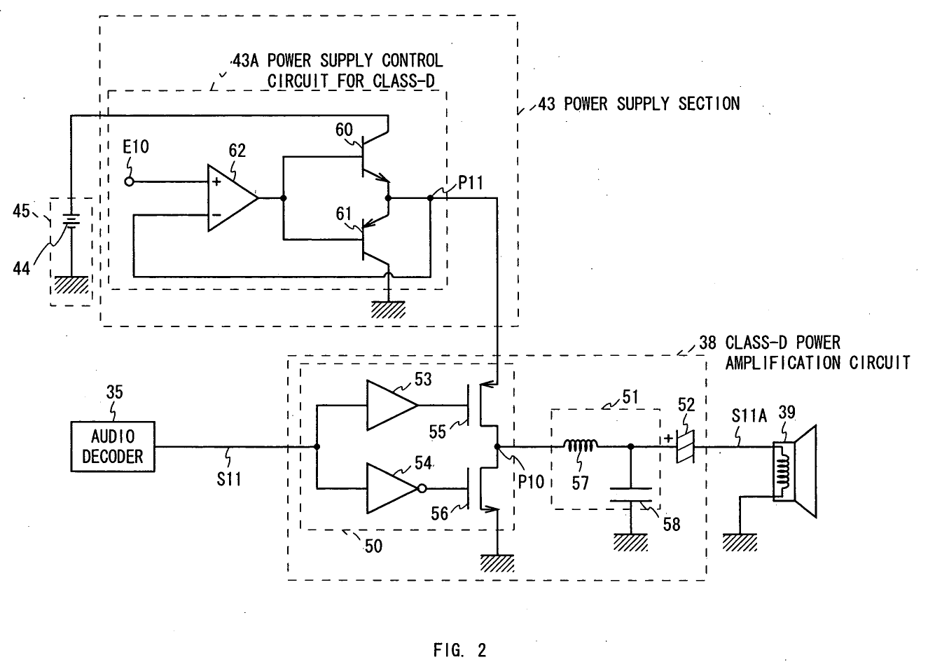

FIG. 2 shows a part of the recording and reproduction device 20 illustrated by FIG. 1: an internal configuration of the class-D power amplification circuit 38 and the power supply control circuit for class-D 43A inside the power supply section 43.

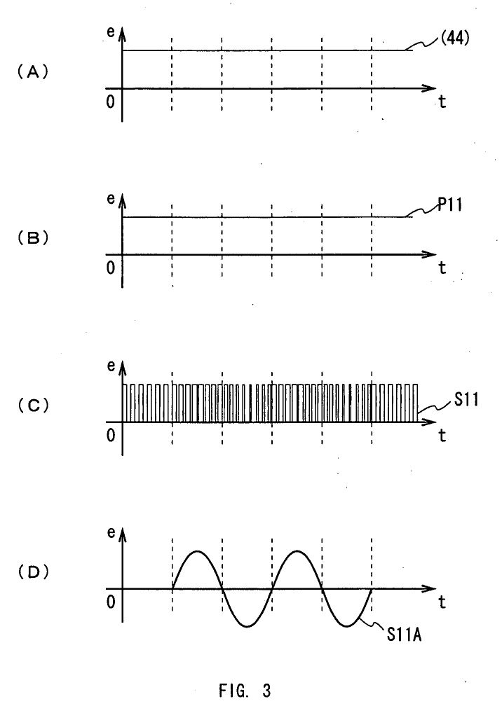

The audio decoder 35 supplies the audio signal S11 (FIG. 3(C)), which has been pulse width modulated, to the class-D power amplification circuit 38. In addition, the power supply control circuit for class-D 43A supplies the power supply voltage (FIG. 3(A)) from the secondary battery 44 to the class-D power amplification circuit 38.

The class-D power amplification circuit 38 includes serially connected circuits: a single-ended class-D amplifier 50, a low-pass filter 51, and a coupling capacitor 52. In the class-D amplifier 50, gates of a PMOS transistor 55 and NMOS transistor 56 are connected to output ports of an amplification circuit 53 and inverting amplification circuit 54, respectively. The amplification circuit 53 and the inverting amplification circuit 54 are connected to one another through a connection midpoint which is equivalent to an output port of the audio decoder 35. Both MOS transistors 55 and 56 operate alternately.

Drains of the PMOS transistor 55 and NMOS transistor 56 are connected to one another and then connected to the low-pass filter 51. A source of the PMOS transistor 55 is connected to an output port of the power supply control circuit for class-D 43A, while a source of the NMOS transistor 56 is grounded.

The low-pass filter 51 includes a coil 57 whose one end is connected to a connection midpoint P10 which is equivalent to a common drain where the drains of the PMOS transistor 55 and NMOS transistor 56 are connected to one another and other end is connected to the coupling capacitor 52; and a capacitor 58 whose one end is connected to the other end of the coil 57 and other end is grounded.

The power supply control circuit for class-D 43A includes a pair of transistors 60 and 61: a NPN transistor 60 for outputting a current and a PNP transistor 61 for absorbing a current. In addition, the power supply control circuit for class-D 43A includes an error amplifier 62 for correcting a voltage.

After bases of the NPN transistor 60 and PNP transistor 61 are connected to one another, these bases are connected to an output port of the error amplifier 62. After emitters of the NPN transistor 60 and PNP transistor 61 are connected to one another, these emitters are connected to the source of the PMOS transistor 55 of the class-D power amplification circuit 38. While a collector of the NPN transistor 60 is connected to the secondary battery 44, the collector of the PNP transistor 61 is grounded.

The error amplifier 62 includes an operational amplifier with two input ports and one output port. One of the input ports is connected to a predetermined voltage generator (not shown) to be kept at a reference potential E10. The other end of the input ports is connected to a connection midpoint P11 that is equivalent to a common emitter where the emitters of the NPN transistor 60 and PNP transistor 61 are connected to one another.

The power supply control circuit for class-D 43A supplies a current from the secondary battery 15 to the class-D amplifier 50 of the class-D power amplification circuit 38 through the NPN transistor 60. In addition, in the error amplifier 62, to hold a differential voltage measured between the connection midpoint P11 where the emitters of the NPN transistor 60 and PNP transistor 61 are connected to one another and the reference potential E10 at a constant level, the power supply control circuit for class-D 43A applies the differential voltage to the common base of the NPN transistor 60 and PNP transistor 61 as a correction voltage.

In the class-D power amplification circuit 38, at a time when the audio signal S11 which corresponds to the PWM signal supplied from the audio encoder 35 is supplied alternately to the bases of the PMOS transistor 55 and NMOS transistor 56 through the amplification circuit 53 and the inverting amplification circuit 54, the connection midpoint P10 puts together drain currents of the PMOS transistor 55 and NMOS transistor 56 of the class-D amplifier 50 which are supplied from the secondary battery 44 via the power supply control circuit for class-D 43A and outputs it to a subsequent stage of the low-pass filter 51.

The low-pass filter 51 integrates the audio signal S11, which has been amplified by the class-D amplifier 50, by the combination of the coil 57 and the capacitor 58 to reproduce an original sine-wave audio signal S11A. The low-pass filter 51 then outputs the audio signal S11A to a speaker 39 after removing direct-current components through a subsequent stage of the coupling capacitor 52.

### (1-3) Operation and Effect in First Embodiment

In the class-D power amplification circuit 38 of the recording and reproduction device 20 with the above configuration, the coil 57 which is a part of the low-pass filter 51 accumulates energy during a negative half-cycle of the sine-wave audio signal S11A which is output from the class-D amplifier 50 through the low-pass filter 51, and this generates a back electromotive force.

At this time, in the class-D power amplification circuit 38, the current which is generated by the back electromotive force at the coil 57 is fed into the connection midpoint P11, which is the common emitter of the NPN transistor 60 and PNP transistor 61 of the power supply control circuit for class-D 43A, through the connection midpoint P10, which is the common drain of the PMOS transistor 55 and NMOS transistor 56 of the class-D amplifier 50, and the source of the PMOS transistor 55.

In the power supply control circuit for class-D 43A, the current fed from the class-D power amplification circuit 38 flows into the ground through the connection point P11, which is the common emitter of the NPN transistor 60 and PNP transistor 61, and the collector of the PNP transistor 61.

That prevents the current which is generated by the back electromotive force at the coil 57 from flowing into a feedback loop of the error amplifier 62 in the power supply control circuit for class-D 43A from the class-D power amplification circuit 38. This prevents the voltage at the emitter of the NPN transistor 60 (i.e. at the connection midpoint P11) from changing during the negative half-cycle of the sine-wave audio signal S11A (FIG. 3(B)).

Accordingly, even if the class-D power amplification circuit 38 produces the back electromotive force at the coil 51 during the negative half-cycle of the audio signal S11A which is a sine-wave output from the class-D amplifier 50 through the low-pass filter 57, that prevents the voltage of the audio signal S11A from being distorted (FIG. 3(D)).

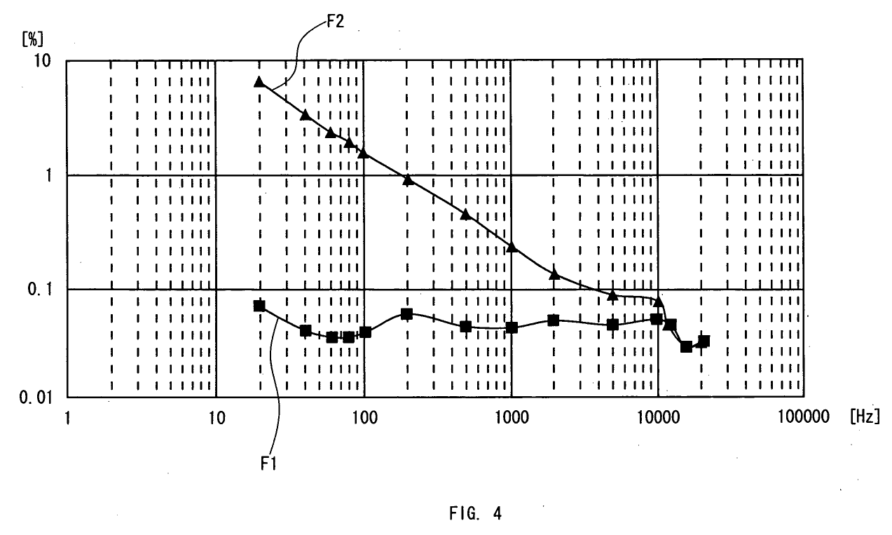

FIG. 4 shows characteristic graphs F1 and F2, where the distortion rate of the voltage of the audio signal S11A, which is a sine-wave output from the class-D power amplification circuit 38, is measured for both the power supply control circuit for class-D 43A with a current absorber of the PNP transistor 61, and the power supply control circuit for class-D 43A without the PNP transistor 61: the cutoff frequency of the low-pass filter is 20 [kHz], the internal resistance of the speaker 39 is 16 [Ω], and the frequency of the audio signal S11A changes around 1 [kHz] and 12 [dBm].

Among the characteristics graphs F1 ad F2 in FIG. 4, according to the characteristic graph F1 where the power supply control circuit for class-D 43A is equipped with a current absorber of the PNP transistor 61, the distortion rate of the voltage of the audio signal S11A is below 0.1 [%] regardless of the frequency of the audio signal S11A. According to the characteristic graph F2 where the power supply control circuit for class-D 43A is not equipped with the PNP transistor 61, the more the frequency of the audio signal S11A decreases the more the distortion rate of the voltage increases.

According to the above configuration, the power supply control circuit for class-D 43A of the recording and reproduction device 20 includes the PNP transistor 61 for absorbing a current whose emitter and base are connected to those of the NPN transistor 60 and collector is grounded. Accordingly, if the coil 57 which is a part of the low-pass filter 51 of the class-D power amplification circuit 38 generates the back electromotive force, the current which is generated by the back electromotive force flows into the ground through the PNP transistor 61 for absorbing the current. Therefore, even if the class-D power amplification circuit 38 produces the back electromotive force at the coil 51 during the negative half-cycle of the audio signal S11A which is a sine-wave output from the class-D amplifier 50 through the low-pass filter 57, that prevents the voltage of the audio signal S11A from being distorted. Thus, the power supply control circuit for class-D 43A can effectively maintain the quality of the sound of the audio signal S11A.

### (2) Second Embodiment

### (2-1) Configuration of Recording and Reproduction Device

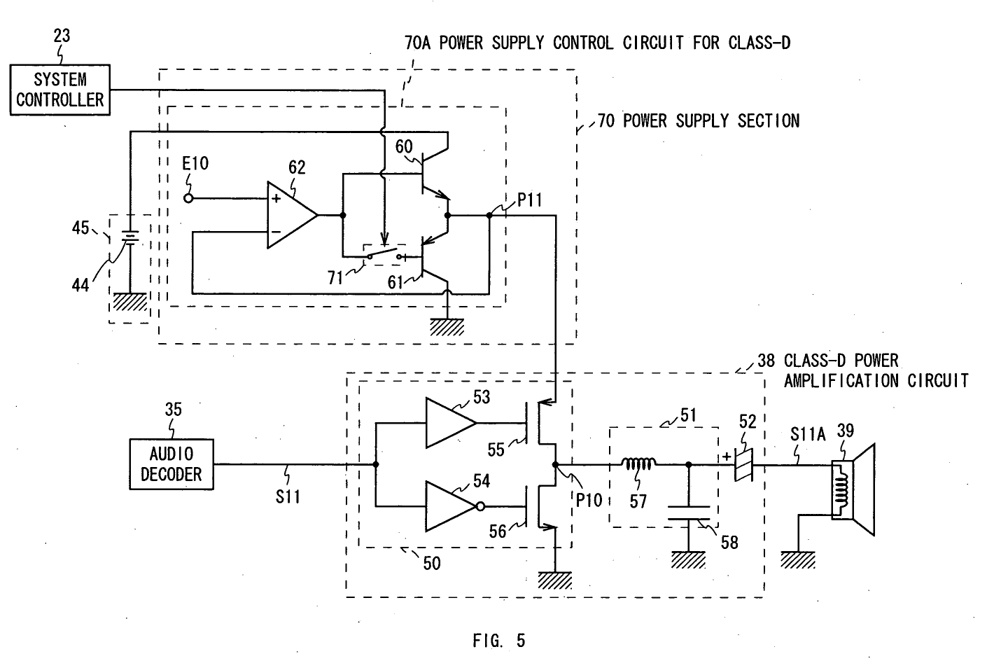

A recording and reproduction device (not shown) according to a second embodiment of the present invention has the same configuration as the recording and reproduction device 20 shown in FIG. 1 except the following points: the internal configuration of a power supply section 70 (illustrated by FIG. 5 below) and the control process of the system controller 23 are different.

### (2-2) Configuration of a Power Supply Control Circuit for Class-D and a Class-D Power Amplification Circuit according to Second Embodiment

FIG. 5 (whose parts have been designated by the same symbols and marks as the corresponding parts of FIG. 2) shows the internal configuration of a power supply control circuit for class-D 70A in the power supply section 70 according to a second embodiment of the present invention. The configuration of the class-D power amplification circuit 38 shown in FIG. 5 is the same as that of the class-D power amplification circuit 38 shown in FIG. 2.

The configuration of the power supply control circuit for class-D 70A is the same as that of the class-D power amplification circuit 43A in the power supply section 43 shown in FIG. 2 except the following point: the power supply control circuit for class-D 70A includes a switching circuit 71, which is switched by the system controller 23, between the output port of the error amplifier 62 and the base of the PNP transistor 61 for absorbing a current.

The power supply control circuit for class-D 70A supplies a current from the secondary battery 15 to the class-D amplifier 50 of the class-D power amplification circuit 38 through the NPN transistor 60. In addition, in the error amplifier 62, to hold a differential voltage measured between the connection midpoint P11 where the emitters of the NPN transistor 60 and PNP transistor 61 are connected to one another and the reference potential E10 at a constant level, the power supply control circuit for class-D 70A applies the differential voltage to the common base of the NPN transistor 60 and PNP transistor 61 as a correction voltage.

In the power supply control circuit for class-D 70A, when the system controller 23 switches the switching circuit 71 on, the current which is generated by the back electromotive force at coil 57 of the class-D power amplification circuit 38 flows into the ground through the connection midpoint P11 and the collector of the PNP transistor 61. When the switching circuit 71 is switched off, the PNP transistor 61 does not work due to the disconnected base and the current from the class-D power amplification circuit 38 therefore flows into the feedback loop of the error amplifier 62.

### (2-3) Operation and Effect in Second Embodiment

In the power supply control circuit for class-D 70A of the recording and reproduction device (not shown) with the above configuration, when a user chooses a mode requiring good quality of the sound which is output from the speaker 39 in accordance with the audio signal S11A, the system controller 23 switches the switching circuit 71 on.

And then, in the class-D power amplification circuit 38, the coil 57 which is a part of the low-pass filter 51 accumulates energy during a negative half-cycle of the sine-wave audio signal S11A output from the class-D amplifier 50 through the low-pass filter 51, and this generates a back electromotive force.

At this time, in the class-D power amplification circuit 38, the current which is generated by the back electromotive force at the coil 57 is fed into the connection midpoint P11, which is the common emitter of the NPN transistor 60 and PNP transistor 61 of the power supply control circuit for class-D 43A, through the connection midpoint P10, which is the common drain of the PMOS transistor 55 and NMOS transistor 56 of the class-D amplifier 50, and the source of the PMOS transistor 55.

In the power supply control circuit for class-D 70A, the current fed from the class-D power amplification circuit 38 flows into the ground through the connection point P11, which is the common emitter of the NPN transistor 60 and PNP transistor 61, and the collector of the PNP transistor 61.

That prevents the current which is generated by the back electromotive force at the coil 57 from flowing into the feedback loop of the error amplifier 62 in the power supply control circuit for class-D 70A from the class-D power amplification circuit 38. This prevents the voltage at the emitter of the NPN transistor 60 from changing during the negative half-cycle of the sine-wave audio signal S11A.

Accordingly, even if the class-D power amplification circuit 38 produces the back electromotive force at the coil 51 during the negative half-cycle of the audio signal S11A which is a sine-wave output from the class-D amplifier 50 through the low-pass filter 57, that prevents the voltage of the audio signal S11A from being distorted.

By contrast, in the power supply control circuit for class-D 70A, when a user chooses, instead of requiring good sound quality, a mode for saving power to use the device for longer hours, the system controller 23 switches the switching circuit 71 off.

And then, in the class-D power amplification circuit 38, the coil 57 which is a part of the low-pass filter 51 accumulates energy during a negative half-cycle of the sine-wave audio signal S11A, and this generates a back electromotive force. The current which is generated by the back electromotive force is fed into the connection midpoint P11, which is the common emitter of the NPN transistor 60 and PNP transistor 61 of the power supply control circuit for class-D 70A.

Therefore, in the power supply control circuit for class-D 70A, the current fed from the class-D power amplification circuit 38 flows into the feedback loop of the error amplifier 62 through the connection point P11, and the voltage at the emitter of the NPN transistor 60 for outputting a current changes only during the negative half-cycle of the sine-wave audio signal S11A. Even if the error amplifier 62 corrects the power supply voltage of the secondary battery 44 to hold it at a constant level, the voltage continues to change. On the other hand, this saves power because the PNP transistor 61 for absorbing a current stops operating.

According to an experiment where the frequency of the sine-wave audio signal S11A is 1 [kHz] and the output voltage of the speaker 39 is 0.1 [mW] and the power supply control circuit for class-D 70A is equipped with the PNP transistor 61 for absorbing a current, the total power (system power) of the power supply control circuit for class-D 70A and the class-D power amplification circuit 38 is 5.3 [mW]. By contrast, in a case in which the power supply control circuit for class-D 70A is not equipped with the PNP transistor 61 for absorbing a current, the total power is 2.4 [mW].

According to the above configuration, the power supply control circuit for class-D 43A of the recording and reproduction device 20 includes the PNP transistor 61 for absorbing a current whose emitter and base are connected to those of the NPN transistor 60 and collector is grounded; and the switching circuit 71 in front of the base of the PNP transistor. The switching circuit 71 is switched on or off in response to a user's operation. Accordingly, if a user chooses a mode requiring good quality of the sound of the audio signal S11A, the PNP transistor 61, the current generated by the back electromotive force at coil 57 which is a part of the low-pass filter 51 of the class-D power amplification circuit 38 is fed into the ground, and this maintains good quality of the sound of the audio signal S11A. If a user chooses a mode for saving power to use the device for longer hours, the PNP transistor 61 stops operating to save the power. Thus, the power supply control circuit for class-D 43A allows a user to choose one of the modes for maintaining sound quality or saving power.

### (3) Other Embodiments

In the above first and second embodiments, the present invention is applied to the power supply control circuits for class-D 43A and 70A of the power supply circuits 43 and 70 of the recording and reproduction device 20 (FIG. 1). However, the present invention is not limited to this. Instead of the recording and reproduction device for magneto optical discs, the present invention may be applied to a device where a power supply voltage from a direct-current power source is supplied, while being controlled at constant voltage, to an amplification circuit performing a differential operation alternately in accordance with a signal level of an input signal: a recording and/or playback device and video camcorder for DVD (Digital Versatile Disc) and CD (Compact Disc), mobile phones, and various electronic devices.

In addition, the class-D power amplification circuit 38 including the class-D amplifier 50, the low-pass filter 51 and the coupling capacitor 52 is applied to as an amplification circuit which performs a differential operation alternately in response to a signal level of the audio signal (input signal) S11. In addition to that, various kinds of amplification circuits capable of performing class-D amplification (digital amplification) may be applied. The secondary battery 44 (such as lithium-ion batteries) is applied to as a direct-current power source. In addition to that, other secondary batteries such as nickel-cadmium battery, primary batteries such as manganese dry battery and mercury battery, and the AC adopter 42 connected to a domestic power source may be applied as the direct-current power source.

In the above first and second embodiments, the NPN transistor 60 for outputting a current in the power supply control circuits for class-D 43A and 70A is applied to as a first transistor for outputting a current whose collector is connected to a direct-current power source and emitter is connected to an amplification circuit. However, the present invention is not limited to this. Instead of the bipolar transistor, other transistors capable of supplying the power supply voltage of the secondary battery (direct-current power source) 44 to outside, such as FET (field-effect transistor), may be applied.

In addition, in the first and second embodiments, the error amplifier 62 in the power supply control circuits for class-D 43A and 70A is applied to as an error amplifier whose output port is connected to the base of the NPN transistor (first transistor) 60 for outputting a current and which performs feedback control to hold a difference between the predetermined reference potential E10 and a potential at the emitter of the NPN transistor (first transistor) 60 for outputting a current at a constant level. However, the present invention is not limited to this. Various error amplifiers, which are capable of correcting the power supply voltage of the secondary battery (direct-current power source) 44 to maintain it at a constant level, may be applied.

Furthermore, in the first and second embodiments, the PNP transistor 61 for absorbing a current in the power supply control circuits for class-D 43A and 70A is applied to as a second transistor for absorbing a current whose emitter and base are connected to those of the NPN transistor (first transistor) 60 and collector is grounded. However, the present invention is not limited to this. Instead of the bipolar transistor, Other transistors (such as FET (field-effect transistor)) capable of feeding the current, which is supplied from the class-D power amplification circuit (amplification circuit) 38 in accordance with predetermined timing of the audio signal (input signal) S11A, into the ground may be applied.

Furthermore, in the second embodiment, the switching circuit 71 which is selectively switched on or off in response to the control of the system controller 23 is applied to as switching means connected between the output port of the error amplifier 62 and the base of the PNP transistor (second transistor) 61 for absorbing a current and which is selectively switched on or off in response to an external operation. Other switching means, which are capable of switching the PNP transistor (second transistor) 61 for absorbing a current on or off, may be applied.

### INDUSTRIAL APPLICABILITY

The power supply control circuit can be applied to portable audio devices, mobile phones and the like.

### DESCRIPTION OF SYMBOLS

20 . . . RECORDING AND REPRODUCTION DEVICE, 21 . . . MAGNETO OPTICAL DISC, 23 . . . SYSTEM CONTROLLER, 35 . . . AUDIO DECODER, 38 . . . CLASS-D POWER AMPLIFICATION CIRCUIT, 39 . . . SPEAKER, 43, 70 . . . POWER SUPPLY SECTION, 43 A, 70 A . . . POWER SUPPLY CONTROL CIRCUIT FOR CLASS-D, 44 . . . SECONDARY BATTERY, 50 . . . CLASS-D AMPLIFIER, 51 . . . LOW-PASS FILTER, 52 . . . COUPLING CAPACITOR, 57 . . . COIL, 60 . . . NPN TRANSISTOR, 61 . . . PNP TRANSISTOR, 62 . . . ERROR AMPLIFIER, 71 . . . SWITCHING CIRCUIT

1. A power supply control circuit for controlling a power supply voltage of a direct-current power source at a constant level and supplying the power supply voltage to an amplification circuit performing a differential operation alternately in accordance with a signal level of an input signal, said power supply control circuit comprising:
a first transistor whose collector is connected to said direct-current power source and emitter is connected to said amplification circuit, for outputting a current;
an error amplifier whose output port is connected to a base of said first transistor, for performing feedback control to hold a difference between a predetermined reference potential and a potential at the emitter of said first transistor at a constant level;
a second transistor whose emitter is mutually connected to the emitter of said first transistor, base is mutually connected to the base of said first transistor and collector is grounded, for absorbing a current; and
switching means connected between the output port of said error amplifier and the base of said second transistor, said switching means being selectively switched on or off in response to external control, wherein
when said switching means is switched on in response to said external control, an emitter current of said first transistor is supplied to said amplification circuit while a current that is supplied at certain timing determined by said input signal from said amplification circuit is fed into the ground through said second transistor, and when said switching means is switched off in response to said external control, the output port of said error amplifier is disconnected from the base of said second transistor to stop operation of said second transistor.

2. The power supply control circuit according to claim 1, comprising
switching means connected between the output port of said error amplifier and the base of said second transistor, said switching means being selectively switched on or off in response to an external operation.
